(19) United States
(12) Patent Application Publication
(10) Pub. No.: US 2013/0134036 A1
(43) Pub. Date: May 30, 2013

(54) Equipment for Making IC Shielding Coating Layer and Metal Shielding Layer of IC

(71) Applicants: CHAO-LUN LIU, Taipei City (TW); YAU-HUNG CHIOU, Taipei City (TW); SHU-HUI FAN, Taipei City (TW)

(72) Inventors: CHAO-LUN LIU, Taipei City (TW); YAU-HUNG CHIOU, Taipei City (TW); SHU-HUI FAN, Taipei City (TW)

(73) Assignee: CHENMING MOLD IND. CORP., Taipei City (TW)

(21) Appl. No.: 13/450,843

(22) Filed: Apr. 19, 2012

(30) Foreign Application Priority Data
Nov. 29, 2011 (TW) 100143653

(51) Int. Cl. C23C 14/35; C23C 14/58

(52) U.S. Cl. 204/298.05; 204/298.16

(57) ABSTRACT

Equipment for making IC shielding coating layer and a metal shielding layer of IC. The equipment comprises a base, a work support, a plurality of medium frequency magnetron targets and a plurality of multi-arc ion targets. The base comprises a chamber. The work support is disposed in the chamber and movably connected with a plurality of rotation axes. Each rotation axes comprises at least one fixture. The fixture is used to put at least one IC. Each medium frequency magnetron target and each multi-arc ion target are disposed in the chamber. The medium frequency magnetron targets and the multi-arc ion targets are used to sputter a metal material over the IC to form at least one metal shielding layer on a surface of the IC.

### CROSS-REFERENCE TO RELATED APPLICATION

This application claims the benefit of Taiwan Patent Application No. 100143653, filed on Nov. 29, 2011, in the Taiwan Intellectual Property Office, the disclosure of which is incorporated herein in its entirety by reference.

### BACKGROUND OF THE INVENTION

1. Field of the Invention

The present invention relates to equipment for making IC shielding coating layer and a metal shielding layer of IC, in particular to the equipment for making IC shielding coating layer and the metal shielding layer of IC by using a physical vapor deposition (PVD) process to produce an IC with a surface with an electromagnetic shielding effect.

2. Description of the Related Art

As science and technology advance, the electronic product has an increasingly smaller size and an increasing powerful function. Therefore, the complexity and density of the integrated circuit (IC) become higher, the conductive transmission wire and the power supply or other components having a higher working frequency installed on the printed circuit board will produce electromagnetic waves, so that an electromagnetic interference (EMI) with other electronic components may occur. Therefore, it is an important issue to find a way to overcome the influence of electromagnetic interference on the circuit.

In general, a conventional printed circuit board usually comes with a metal casing for covering a portion of the printed circuit board to protect the printed circuit board from being affected by electromagnetic interference. In FIG. 1, the metal casing 11 is covered onto an IC chip 12 of the printed circuit board 1 to overcome the electromagnetic interference problem. Since the metal casing 11 is assembled onto the printed circuit board 1 by independent manufacturing processes and additional labor, the manufacturing cost is very high. In addition, the metal casing 1 is usually fixed onto the printed circuit board 1 by soldering or other methods, so that the size of the printed circuit board 1 becomes larger. When it is necessary to maintain, repair or replace the IC chip 12, the metal casing 11 must be removed first, and thus it is very inconvenient and easy to damage the printed circuit board 1. In addition, the heat dissipation is also a major issue.

With reference to FIG. 2 for another conventional IC shielding layer, a shielding layer 21 is formed on a printed circuit board 2 having a plurality of IC chips 22, and this manufacturing method requires a process of forming the shielding layer 21 on the printed circuit board 2, and thus ruining the original manufacturing process, and causing tremendous inconvenience. In addition, this manufacturing method can form the shielding layer on a plurality of IC chips, and slice into single IC chips for use, and the shielding layer cannot be formed directly on the single IC chip, and the flexibility is limited. Therefore, it is a main subject of the present invention to overcome the problem of the prior art having a having IC metal casing, a high manufacturing cost, a poor heat dissipating effect, an inconvenient use of the shielding layer formed on the plural IC chips, and a poor flexibility.

### SUMMARY OF THE INVENTION

In view of the shortcomings of the prior art, it is a primary objective of the present invention to provide equipment for making IC shielding coating layer and a metal shielding layer of IC to overcome the drawbacks of the prior art that uses a metal casing as the electromagnetic shielding of the IC and requires another machine for the manufacturing, assembling and formation to incur higher manufacturing time and cost.

To achieve the aforementioned objective, the present invention provides equipment for making IC shielding coating layer comprising a base, a work support, a plurality of medium frequency magnetron targets and a plurality of multi-arc ion targets. The base comprises a chamber. The work support is disposed in the chamber and movably connected with a plurality of rotation axes. Each rotation axes comprises at least one fixture. The fixture is used to put at least one IC. Each medium frequency magnetron target and each multi-arc ion target are disposed in the chamber. The medium frequency magnetron targets and the multi-arc ion targets are used to sputter a metal material over the IC to form at least one metal shielding layer on a surface of the IC.

Preferably, the equipment for making IC shielding coating layer of the present invention further comprises vacuum equipment installed in the chamber for evacuating air from the chamber.

Preferably, the equipment for making IC shielding coating layer of the present invention further comprises heating equipment installed in the chamber for increasing the temperature inside the chamber.

Preferably, the equipment for making IC shielding coating layer of the present invention further comprises bias equipment installed in the chamber for performing an ion cleaning of the IC.

Preferably, the medium frequency magnetron target and the multi-arc ion target are further used for sputtering a compound over the at least one metal shielding layer to form an insulating layer.

Preferably, the metal material comprises titanium, nickel, copper and stainless steel.

Preferably, the multi-arc ion target or the medium frequency magnetron target is used for sputtering titanium or nickel over the surface of the IC to form a first metal shielding layer, and then the medium frequency magnetron target or the multi-arc ion target is used for sputtering copper over the first metal shielding layer to form a second metal shielding layer, and then the multi-arc ion target or the medium frequency magnetron target is used for sputtering stainless steel or nickel over the second metal shielding layer to form a third metal shielding layer, and finally the medium frequency magnetron target and the multi-arc ion target are used for sputtering an oxide, a nitride, a carbide or the compound of any combination of the above over the third metal shielding layer to form the insulating layer.

Preferably, the work support may be a hollow circular tray.

Preferably, the work support comprises a plurality of connecting ends equidistantly disposed on a surface of the work support and provided for connecting the rotation axes respectively.

Preferably, the work support is a multi-axis revolution and rotation structure, and the work support and the connecting end are rotate to drive the rotation axis to revolve and rotate.

Preferably, the medium frequency magnetron targets may be disposed on both external side and internal side of the work support, and the multi-arc ion targets are disposed on the external side of the work support.

Preferably, a portion of the medium frequency magnetron targets may be disposed at an end of the work support, and the other portion of the medium frequency magnetron targets are disposed at the other opposite end of the work support.

Preferably, each of the medium frequency magnetron targets and each of the multi-arc ion targets have a movable gate for protecting the medium frequency magnetron target or the multi-arc ion target before the layer coating takes place, in order to avoid sputtering the spilling metal material by the medium frequency magnetron target or the multi-arc ion target when the layer coating takes place.

In summary, the equipment for making IC shielding coating layer and the metal shielding layer of IC in accordance the present invention have one or more of the following advantages:

(1) The equipment for making IC shielding coating layer uses a PVD process to sputter one or more layers of metal materials onto a surface of an IC to form a metal shielding layer, so that the IC has an electromagnetic shielding effect. It is no longer to use a metal cover plate for shielding anymore, so that the assembling of the metal cover plate is not required. The layer coating method is used for forming the metal shielding, so that it is no need to consider the corresponding dimensions of the IC and the metal cover plate, and the cost can be lowered effectively.

(2) When the equipment for making IC shielding coating layer is used for performing the layer coating of an IC, all manufacturing processes are finished inside the chamber without the need of transportation or moving, and the work support in the equipment is designed with a multi-axis revolution and rotation structure, and the work support can be used for putting a plurality of ICs, and many medium frequency magnetron targets and multi-arc ion targets are disposed at different points on the external side of the work support, so as to expedite the layer coating of the IC and lower the manufacturing time.

(3) The equipment for making IC shielding coating layer further uses the medium frequency magnetron targets and multi-arc ion targets to sputter an oxide, a nitride, a carbide, or a compound with a combination of the above over the final layer on the metal shielding layer to form an insulating layer after the metal shielding layer completes sputtering the metal material over the IC. The insulating layer can prevent the solder from touching the metal shielding layer during the soldering process, which may result in a short circuit caused by the contact between the metal shielding layer and the circuit.

### BRIEF DESCRIPTION OF THE DRAWINGS

FIG. 1 is a schematic view of a conventional electromagnetic shielding of IC;

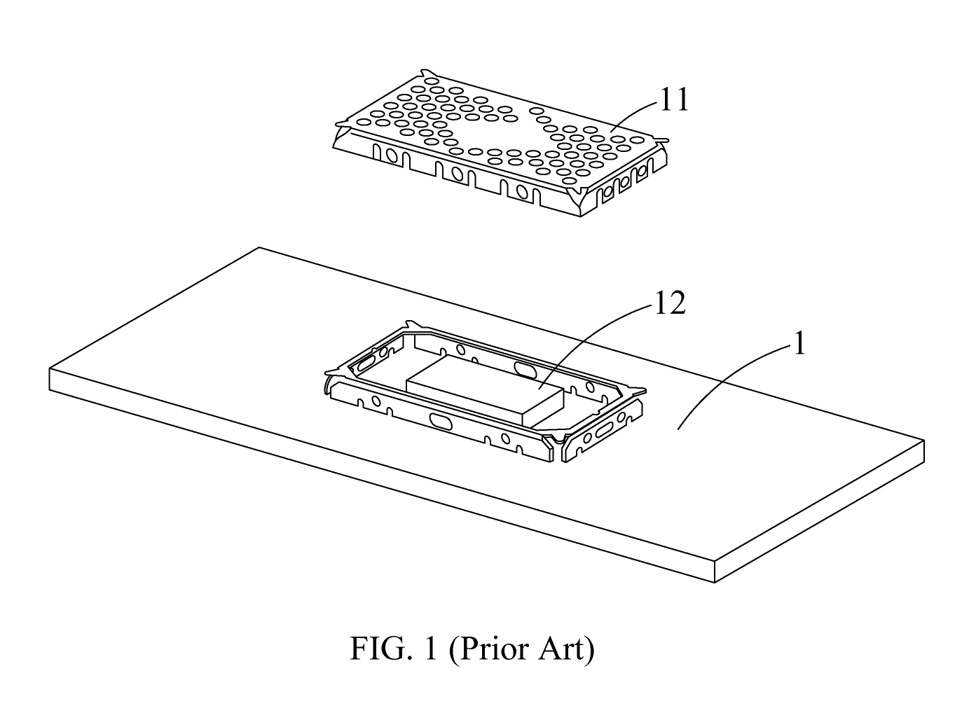

FIG. 2 is another schematic view of a conventional electromagnetic shielding of IC;

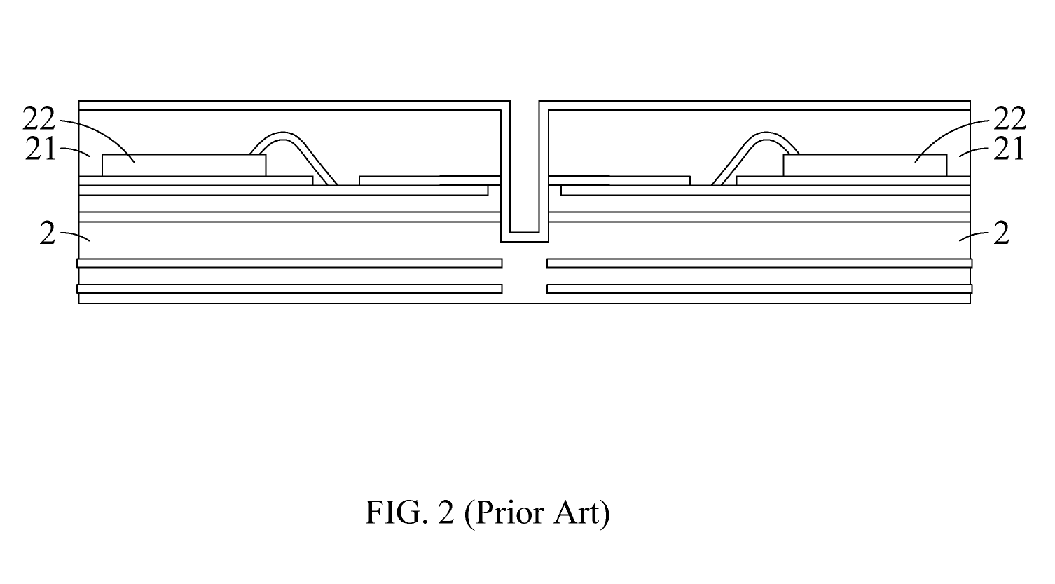

FIG. 3 is a schematic view of equipment for making IC shielding coating layer in accordance with a preferred embodiment of the present invention;

FIG. 4 is a schematic view of a rotation axis in accordance with a preferred embodiment of the present invention; and

FIG. 5 is a schematic view of a metal shielding layer of IC in accordance with a preferred embodiment of the present invention.

### DETAILED DESCRIPTION OF THE PREFERRED EMBODIMENTS

The technical characteristics of the present invention will become clear with the detailed description of the preferred embodiments accompanied with the illustration of related drawings as follows. It is noteworthy to point out that the drawings are provided for the purpose of illustrating the present invention and supporting the description of the specification only, but not intended for limiting the scope of the invention, and the drawings are not necessarily drawn with actual proportion and precision.

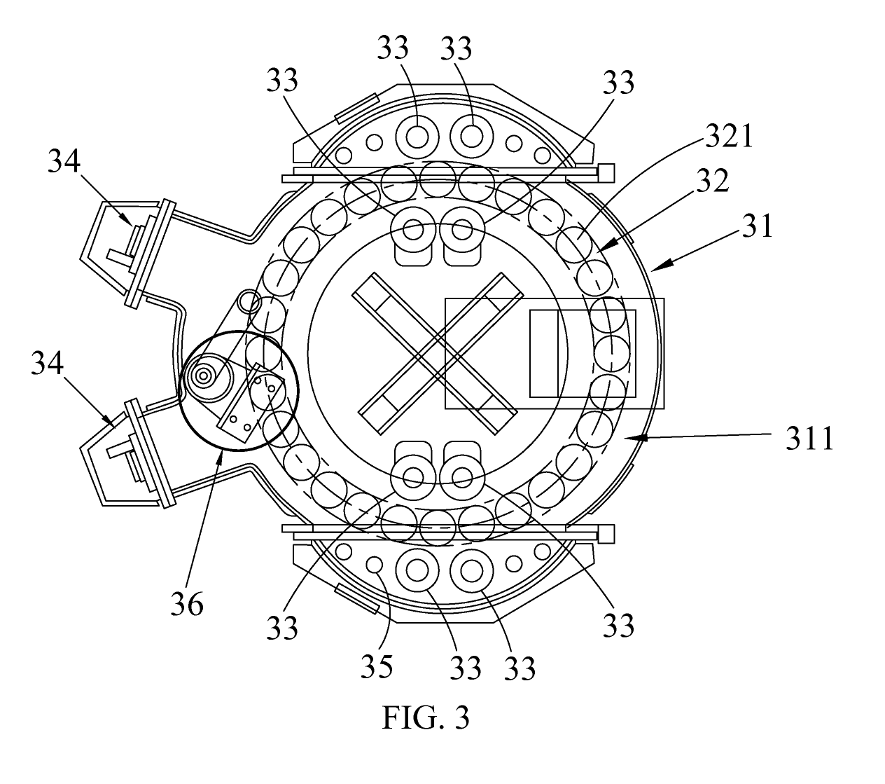

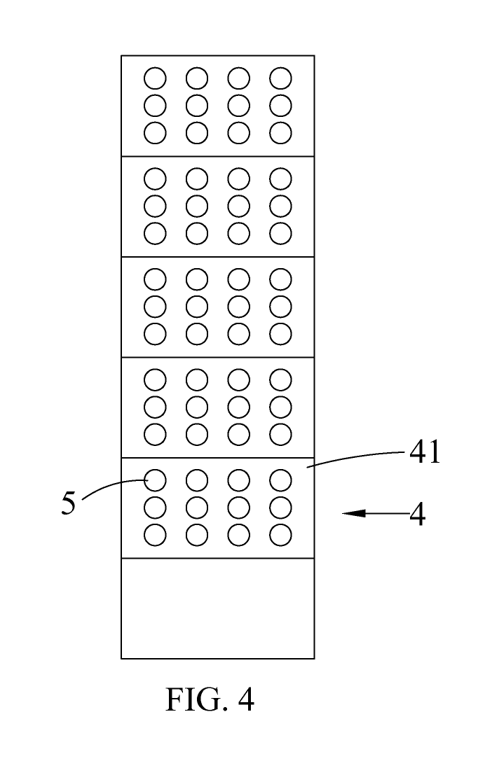

With reference to FIG. 3 for a schematic view of equipment for making IC shielding coating layer in accordance with a preferred embodiment of the present invention. The equipment for making an IC shielding coating layer comprises a base 31, a work support 32, a plurality of medium frequency magnetron targets 33, a plurality of multi-arc ion targets 34, a plurality of heating pipes 35, bias/driving equipment 36 and vacuum equipment (not shown in the figure), wherein the plural heating pipes 35 are the heating equipment of the present invention. The base 31 comprises a chamber 311, and the work support 32, the plurality of medium frequency magnetron targets 33, the plurality of multi-arc ion targets 34, the plurality of heating pipes 35, the bias/driving equipment 36, and the vacuum equipment are installed in chamber 311. The work support 32 comprises a plurality of connecting ends 321 equidistantly disposed on a surface of the work support 32, and the work support 32 is substantially in the form of a hollow circular tray. However, the invention is not limited to this embodiment only, and other shape such as a square shaped tray can be used as well. Each connecting end 321 of the work support 32 is used for movably connecting each rotation axis 4, and each rotation axis 4 has at least one fixture 41, and the fixture 41 is used for putting a plurality of integrated circuits (IC) 5, and the rotation axis 4 is shown in FIG. 4. Wherein, the fixture 41 is capable of putting one integrated circuit 5, and the slicing manufacture is no longer required after the layer coating.

The vacuum equipment is mainly used for vacuuming the air from the chamber 311. Each heating pipe 35 can be used for increasing the working temperature inside the chamber 311 to assist the layer coating, and the heating pipe 35 is generally heated up to the temperature approximately from 150° C. to 300° C., and a temperature control system is used for controlling the temperature, and the precision of the temperature control ranges from 1° C. to 5° C. The bias/driving equipment 36 is used for performing an ion cleaning of the integrated circuit 5 and driving the work support 32 to rotate. The bias equipment 36 adopts a unipolar DC pulsed bias power, DC or pulse voltage which can be an adjustable design, and the DC current approximately ranges from 20 volts to 200 volts, and the pulse voltage approximately ranges from 100 volts to 1000 volts. The work support 32 can be a multi-axis revolution and rotation structure for driving the rotation axis 4 to revolve and rotate, and the multi-axis revolution and rotation structure adopts an inverter to adjust the rotation speed, and the rotation speed approximately ranges from 1 RPM to 60 RPM.

The medium frequency magnetron target 33 and the multi-arc ion target 34 can be used for sputtering a metal material and a compound over the integrated circuit 5, and the metal material includes titanium, nickel, copper, and stainless steel, and the compound includes an oxide, a nitride, a carbide, or any combination of the above. The medium frequency magnetron target 33 is a cylindrical or planar magnetron sputtering target match with the cylindrical or planar metal target, wherein the cylindrical magnetron sputtering target adopts a directional rotation sputtering structure, and the rotation speed approximately ranges from 1 RPM to 40 RPM. The target power of the medium frequency magnetron target 33 is a medium frequency magnetron power. The multi-arc ion target 34 adopts a DC multi-arc power with a current approximately ranging from 100 A to 250 A. Each medium frequency magnetron target 33 and each multi-arc ion target 34 have a movable gate (not shown in the figure) for protecting the medium frequency magnetron target 33 or multi-arc ion target 34 before the layer coating takes place, in order to avoid spilling the metal material sputtered by the medium frequency magnetron target 33 or the multi-arc ion target 34 when the layer coating takes place.

Each medium frequency magnetron targets 33 is mainly disposed on both internal and external sides of the work support 32, and a portion of the medium frequency magnetron targets 33 are disposed at an end of the work support 32, and another portion of the medium frequency magnetron targets 33 are disposed at the other end of the work support 32. The plural multi-arc ion targets 34 are disposed on the external side of the work support 32. In FIG. 3, the work support 32, the plurality of medium frequency magnetron targets 33, the plurality of multi-arc ion targets 34, the plurality of heating pipes 35, bias/driving equipment 36 and vacuum equipment are disposed at appropriate installation positions in the chamber 311 respectively, wherein their installation positions and quantities of this preferred embodiment are used for illustrating the present invention, but the invention is not limited by such arrangement. Each of the forgoing set parameters, current values, rotation speeds, metal materials, and structural designs are provided for illustrating the invention, but not intended for limiting the scope of the invention.

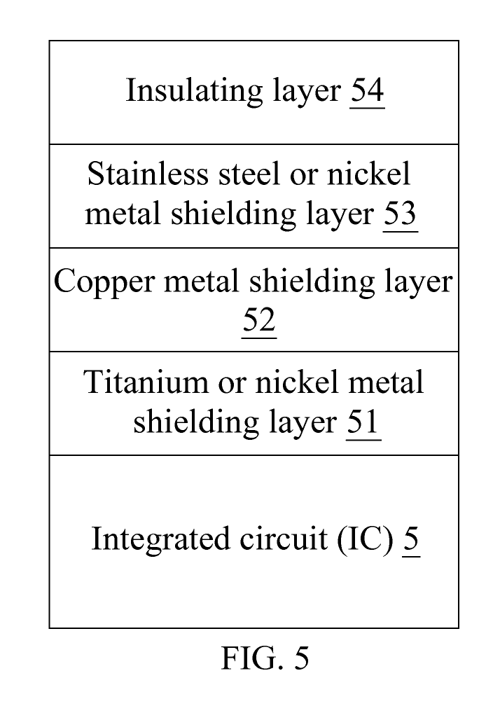

When the equipment for making IC shielding coating layer is used for performing the layer coating of the integrated circuit 5 as described above, vacuum equipment is provided for evacuating the air from the chamber 311, and then a physical manufacturing process is used to perform a surface activation cleaning process of the integrated circuit 5, and the heating pipes 35 and the bias equipment are used for increasing the working temperature inside the chamber 311 and performing an ion cleaning to assist the layer coating of the integrated circuit 5. And then, the multi-arc ion target 34 or medium frequency magnetron target 33 is used for sputtering titanium or nickel over a surface of the integrated circuit 5 to form a first metal shielding layer. In this preferred embodiment, titanium or nickel is sputtered over the integrated circuit 5, so that the first metal shielding layer is a titanium or nickel metal shielding layer 51. And then, the medium frequency magnetron target 33 or the multi-arc ion target 34 sputters copper over the titanium or nickel metal shielding layer 51 to form a copper metal shielding layer 52 (which is a second metal shielding layer). And then, the multi-arc ion target 34 or the medium frequency magnetron target 33 sputters stainless steel or nickel over the copper metal shielding layer 52 to form a stainless or nickel metal shielding layer 53 (which is a third metal shielding layer). Finally, an oxide, a nitride, a carbide, or a compound with any combination of the above is sputtered over the stainless steel or nickel metal shielding layer 53 to form an insulating layer 54 as shown in FIG. 5.

A portion of the medium frequency magnetron targets 33 and multi-arc ion targets 34 is used for the layer coating, or all medium frequency magnetron targets 33 and multi-arc ion targets 34 are used for the layer coating. Since the work support 32 can drive the rotation axis 4 to revolve and rotate, therefore a portion of the medium frequency magnetron targets 33 or multi-arc ion targets 34 can be used for performing the layer coating of the first metal shielding layer. Another portion of the medium frequency magnetron targets 33 or multi-arc ion targets 34 can be used for performing the layer coating of the second metal shielding layer. Another portion of the medium frequency magnetron targets 33 or multi-arc ion targets 34 can be used for performing the layer coating of the third metal shielding layer. The aforementioned arrangement not only expedites the layer coating, but also uniformly sputters the metal materials onto a surface of the integrated circuit. Of course, only a portion of the medium frequency magnetron targets 33 or multi-arc ion target 34 can complete the layer coating of the first metal shielding layer, second metal shielding layer, third metal shielding layer and insulating layer 54, and the aforementioned target sputtering method is just an embodiment adopting the sequence of the operations of each equipment, but the present invention is not limited to such arrangement only.

In summary, the equipment for making IC shielding coating layer in accordance with the present invention can sputter a metal material over a surface of an IC by layer coating to form an electromagnetic shielding to protect the IC and substitute the conventional way of using a metal cover plate as the electromagnetic shielding. In addition, the present invention can sputter the metal material over a single IC, so that the slicing process is no longer required after the layer coating of the IC. In the equipment for making IC shielding coating layer, the way of installing each equipment can expedite the layer coating process, and uniformly sputter the metal material over the surface of the IC, so as to achieve the effects of lowering the cost and the time required for the whole manufacturing process effectively. After a metal material is sputtered over the IC, a compound is sputtered onto the shielding layer to prevent the shielding layer from being contacted with other circuits to cause a short circuit.

In summary, the present invention breaks through the prior art to achieve the expected effects and complies with patent application requirements, and thus is duly filed for patent application. While the invention has been described by means of specific embodiments, numerous modifications and variations could be made thereto by those skilled in the art without departing from the scope and spirit of the invention set forth in the claims.

What is claimed is:

1. A piece of equipment for making IC shielding coating layer, comprising:
a base including a chamber;
a work support disposed in the chamber, and movably connected with a plurality of rotation axes, and each rotation axis having at least one fixture for putting at least one integrated circuit (IC); and
a plurality of medium frequency magnetron targets and a plurality of multi-arc ion targets, disposed in the chamber, and provided for sputtering a metal material over the IC to form at least one metal shielding layer on a surface of the IC.

2. The equipment for making IC shielding coating layer according to claim 1, further comprising vacuum equipment installed in the chamber for evacuating air from the chamber.

3. The equipment for making IC shielding coating layer according to claim 1, further comprising heating equipment installed in the chamber for increasing the temperature inside the chamber.

4. The equipment for making IC shielding coating layer according to claim 1, further comprising bias equipment installed in the chamber for performing an ion cleaning of the IC.

5. The equipment for making IC shielding coating layer according to claim 1, wherein the medium frequency magnetron target and the multi-arc ion target are further used for sputtering a compound over the at least one metal shielding layer to form an insulating layer.

6. The equipment for making IC shielding coating layer according to claim 5, wherein the metal material comprises titanium, nickel, copper and stainless steel.

7. The equipment for making IC shielding coating layer according to claim 6, wherein the multi-arc ion target or the medium frequency magnetron target is used for sputtering titanium or nickel over the surface of the IC to form a first metal shielding layer, and then the medium frequency magnetron target or the multi-arc ion target is used for sputtering copper over the first metal shielding layer to form a second metal shielding layer, and then the multi-arc ion target or the medium frequency magnetron target is used for sputtering stainless steel or nickel over the second metal shielding layer to form a third metal shielding layer, and finally the medium frequency magnetron target and the multi-arc ion target are used for sputtering an oxide, a nitride, a carbide or the compound of any combination of the above over the third metal shielding layer to form the insulating layer.

8. The equipment for making IC shielding coating layer according to claim 1, wherein the work support is a hollow circular tray.

9. The equipment for making IC shielding coating layer according to claim 8, wherein the work support comprises a plurality of connecting ends equidistantly disposed on a surface of the work support and provided for connecting the rotation axes respectively.

10. The equipment for making IC shielding coating layer according to claim 9, wherein the work support is a multi-axis revolution and rotation structure, the work support and the connecting end are rotate to drive the rotation axis to revolve and rotate.

11. The equipment for making IC shielding coating layer according to claim 8, wherein the medium frequency magnetron targets are disposed on both external side and internal side of the work support, and the multi-arc ion targets are disposed on the external side of the work support.

12. The equipment for making IC shielding coating layer according to claim 11, wherein a portion of the medium frequency magnetron targets are disposed at an end of the work support, and the other portion of the medium frequency magnetron targets are disposed at the other opposite end of the work support.

13. The equipment for making IC shielding coating layer according to claim 1, wherein each of the medium frequency magnetron targets and each of the multi-arc ion targets have a movable gate for protecting the medium frequency magnetron target or the multi-arc ion target before the layer coating takes place, in order to avoid sputtering the spilling metal material by the medium frequency magnetron target or the multi-arc ion target when the layer coating takes place.
